(19) United States
(12) Patent Application Publication
(10) Pub. No.: US 2014/0302626 A1
(43) Pub. Date: Oct. 9, 2014

(54) METHOD OF MANUFACTURING DISPLAY AND DEPOSITION APPARATUS FOR THE SAME

(71) Applicant: Samsung Display Co., Ltd., Yongin-City (KR)

(72) Inventors: Cheol-Rae Jo, Yongin-City (KR); Myung-Soo Huh, Yongin-City (KR); Suk-Won Jung, Yongin-City (KR); Choel-Min Jang, Yongin-City (KR); Jeong-Ho Yi, Yongin-City (KR)

(73) Assignee: Samsung Display Co., Ltd., Yongin-City (KR)

(21) Appl. No.: 13/964,020

(22) Filed: Aug. 9, 2013

(30) Foreign Application Priority Data
Apr. 4, 2013 (KR) 10-2013-0036983

(51) Int. Cl. H01L 51/56

(52) U.S. Cl. CPC H01L 51/56
USPC 438/33; 118/504

(57) ABSTRACT

Provided are a method of manufacturing a display that may reduce deposition nonuniformity while concurrently manufacturing a plurality of displays, and a deposition apparatus that may be used in the method, wherein the method includes: preparing a mother substrate having a plurality of regions in a matrix pattern, the mother substrate being for forming a plurality of display units corresponding to the plurality of regions; inserting the mother substrate into a deposition chamber, wherein a deposition source is in the deposition chamber; depositing a material on the mother substrate by using a mask including a plurality of parallel stripe-shaped masking sheets extending in a first direction; and cutting the mother substrate along a periphery of each of the plurality of display units to obtain the plurality of displays.

### CROSS-REFERENCE TO RELATED APPLICATION

This application claims priority to and the benefit of Korean Patent Application No. 10-2013-0036983, filed on Apr. 4, 2013, in the Korean Intellectual Property Office, the disclosure of which is incorporated herein in its entirety by reference.

### BACKGROUND

1. Field

Aspects of the present invention relate to a method of manufacturing a display and a deposition apparatus.

2. Description of the Related Art

In general, a deposition process for forming a particular film on a substrate is included in a display manufacturing process. In the deposition process, a mask includes openings at parts corresponding to regions where the film is to be formed on the substrate. The mask is attached to the substrate or located near the substrate, and then a material released from a source passes through the openings to settle on the predetermined regions of the substrate.

However, a conventional mask or a method of manufacturing a display by using the mask may not easily deposit a uniform film. For example, when a material is deposited to manufacture a plurality of displays at the same time, films deposited on the plurality of displays may not be uniform as compared to one another.

### SUMMARY

Embodiments of the present invention provide a method of manufacturing a display that may reduce deposition nonuniformity while manufacturing a plurality of displays at the same time, and a deposition apparatus that may be used in the method. However, the embodiments described herein are exemplary, and thus, the scope of the present invention is not limited thereto.

According to an aspect of the present invention, there is provided a method of manufacturing a plurality of displays, the method including: preparing a mother substrate having a plurality of regions in a matrix pattern, the mother substrate being for forming a plurality of display units corresponding to the plurality of regions; inserting the mother substrate into a deposition chamber, wherein a deposition source movable in a first direction or a second direction opposite to the first direction is in the deposition chamber; depositing a material on the mother substrate by using a mask including a plurality of parallel stripe-shaped masking sheets extending in the first direction; and cutting the mother substrate along a periphery of each of the plurality of display units to obtain the plurality of displays.

The depositing of the material on the mother substrate may include depositing the material on the mother substrate while a location of the mask with respect to the mother substrate is fixed.

The masking sheets of the mask may correspond to gaps between rows of the plurality of regions of the mother substrate arranged in the first direction.

The mask may not have masking sheets extending in a third direction crossing the first direction.

Each of the plurality of display units may include an organic light-emitting device.

According to an aspect of the present invention there is provided a method of manufacturing a plurality of displays, the method including: preparing a mother substrate having a plurality of regions in a matrix pattern, the mother substrate being for forming a plurality of display units corresponding to the plurality of regions; inserting the mother substrate into a deposition chamber including a deposition source; depositing a material on the mother substrate by using a mask including a plurality of parallel stripe-shaped masking sheets extending in a first direction while moving the mother substrate in at least one of the first direction and a second direction opposite to the first direction; and cutting the mother substrate along a periphery of each of the plurality of display units to obtain the plurality of displays.

The depositing of the material on the mother substrate may include depositing the material on the mother substrate while moving the mother substrate and while a location of the mask with respect to the deposition source is fixed.

The depositing of the material on the mother substrate may include depositing the material on the mother substrate while a location of the mask with respect to the mother substrate is fixed.

The masking sheets of the mask may correspond to gaps between rows of the plurality of regions of the mother substrate arranged in the first direction.

The mask may not have masking sheets extending in a third direction crossing the first direction.

Each of the plurality of display units may include an organic light-emitting device.

According to an aspect of the present invention, there is provided a deposition apparatus including: a deposition chamber including a deposition source movable in a first direction and a second direction opposite to the first direction; and a mask including a plurality of parallel stripe-shaped masking sheets extending in the first direction.

A location of the mask with respect to an inserted mother substrate may be fixed when a material is deposited on the inserted mother substrate.

A mother substrate may have a plurality of regions in a matrix pattern, the mother substrate being for forming a plurality of display units corresponding to the plurality of regions, and the masking sheets of the mask may correspond to gaps between rows of the plurality of regions of the mother substrate arranged in the first direction.

The mask may not have masking sheets extending in a third direction crossing the first direction.

According to an aspect of the present invention, there is provided a deposition apparatus including: a deposition chamber including a deposition source; a mask including a plurality of parallel stripe-shaped masking sheets extending in a first direction; and a transfer unit in the deposition chamber, wherein the transfer unit delivers an inserted mother substrate in at least one of the first direction and a second direction opposite to the first direction while depositing a material on the inserted mother substrate.

A location of the mask with respect to the deposition source may be fixed when the material is deposited on the inserted mother substrate.

A location of the mask with respect to the inserted mother substrate may be fixed when the material is deposited on the inserted mother substrate.

The inserted mother substrate may have a plurality of regions in a matrix pattern, the mother substrate may be for forming a plurality of display units corresponding to the plurality of regions, and the masking sheets of the mask may correspond to gaps between rows of the plurality of regions of the mother substrate arranged in the first direction.

The mask does not have masking sheets extending in a third direction crossing the first direction.

### BRIEF DESCRIPTION OF THE DRAWINGS

The above and other features and aspects of the present invention will become more apparent by describing in detail exemplary embodiments thereof with reference to the attached drawings in which:

FIG. 1 is a plan view schematically illustrating a mask that may be used in a method of manufacturing a display according to an embodiment of the present invention;

FIG. 2 is an exploded perspective view schematically illustrating a manufacturing process of the method of manufacturing a display according to an embodiment of the present invention;

FIG. 3 is a plan view schematically illustrating a display manufactured according to a method of an embodiment of the present invention;

FIG. 4 is a perspective view schematically illustrating a mask that may be used in a method of manufacturing a display according to a comparative example;

FIG. 5 is a plan view schematically illustrating a display manufactured according to a comparative example method;

FIG. 6 is a side cross-sectional view schematically illustrating a manufacturing process of the method of manufacturing a display according to an embodiment of the present invention; and

FIG. 7 is a side cross-sectional view schematically illustrating a manufacturing process of a method of manufacturing a display according to another embodiment of the present invention.

### DETAILED DESCRIPTION

Aspects of the present invention will be described more fully hereinafter with reference to the accompanying drawings, in which embodiments of the invention are shown. These embodiments are provided to assist in conveying the scope of the present invention to one of ordinary skill in the art, but should not be construed as limiting the scope of the present invention to the embodiments shown. Sizes of elements in the drawings may be exaggerated or reduced for convenience of explanation. That is, because sizes and thicknesses of elements in the drawings are exemplary, the present embodiment is not limited thereto.

In embodiments of the invention, x-axis, y-axis, and z-axis may be comprehensively understood rather than being limited to the three axes on a rectangular coordinate system. For example, the x-axis, y-axis, and z-axis may cross one another at right angles but may also indicate different directions that do not cross one another at right angles.

It will be understood that when an element, such as a layer, a film, a region, or a plate, is referred to as being “on” another element, it may be directly on the other element or one or more intervening elements may be present.

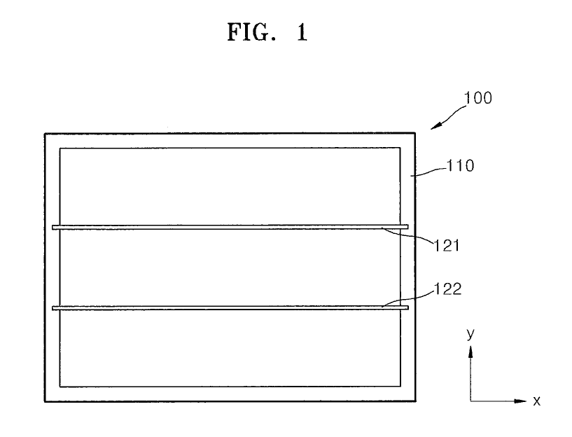

FIG. 1 is a plan view schematically illustrating a mask 100 that may be used in a method of manufacturing a display according to an embodiment of the present invention.

The mask 100, which may be used in the method of manufacturing a display according to an embodiment of the present invention, includes a frame 110 in which openings are formed for a deposition material to pass therethrough, and masking sheets 121, 122 attached to the frame 110. In FIG. 1, the mask 100 is shown as having two masking sheets 121, 122, but a number of the masking sheets is not limited thereto. For example, the mask 100 may have a plurality of parallel stripe-shaped masking sheets 121, 122, etc. that extend in one direction (+x direction).

The mask 100 may be used when a plurality of displays are concurrently (or simultaneously) formed on one large mother substrate. A distance in a −y direction between a part of the frame 110 extending in a +x direction and a first masking sheet 121 may approximately correspond to a length of one side of each display to be prepared on the mother substrate. A distance between the first masking sheet 121 and a second masking sheet 122 may also approximately correspond to a length of one side of each display to be prepared, and a distance a +y direction between a part of the frame 110 extending in a +x direction and the second masking sheet 122 may also approximately correspond to a length of one side of each display to be prepared on the mother substrate. Here, a length extended in one direction (e.g., a +x direction) of each of the masking sheets 121, 122 may approximately correspond to a total length of other sides of each of the plurality of displays to be concurrently (or simultaneously) prepared on the mother substrate.

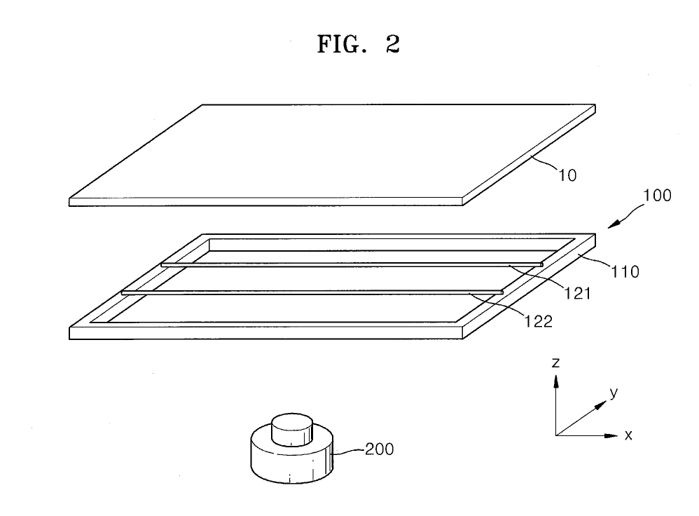

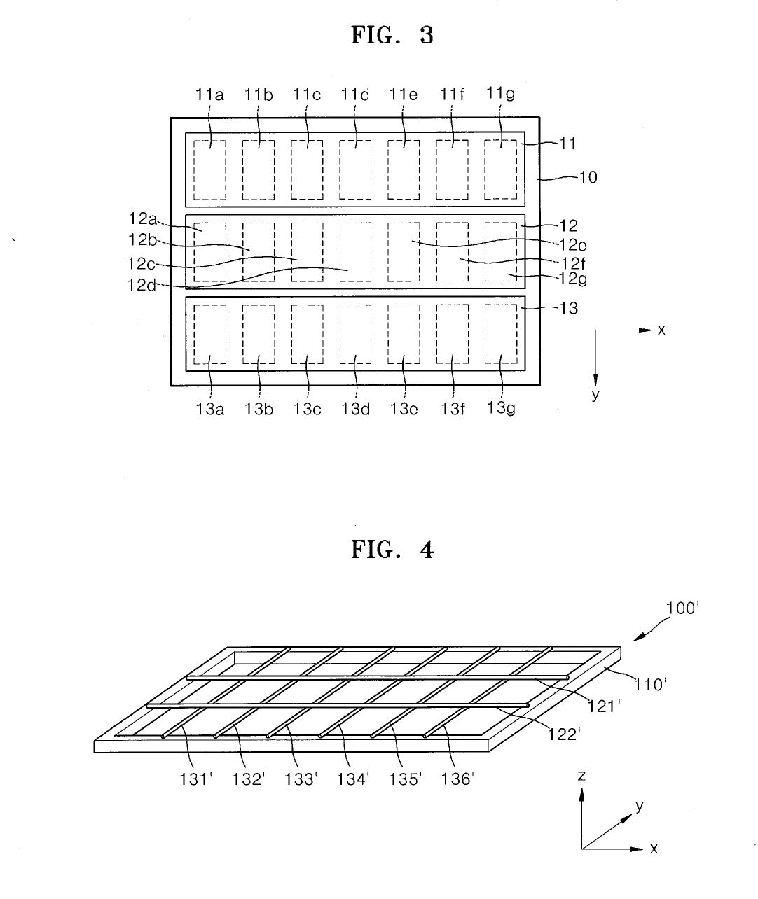

FIG. 2 is an exploded perspective view schematically illustrating one process of a method of manufacturing a display according to an embodiment of the present invention. FIG. 3 is a plan view schematically illustrating a display manufactured according to a method of an embodiment of the present invention.

A mother substrate 10 may have a plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g in a matrix pattern on which a plurality of display units may be formed, respectively. The mother substrate 10 is inserted into a deposition chamber. The mother substrate 10 may be formed of various materials, including a glass material or a plastic material.

The deposition chamber may be a chamber that may deposit a material on a front surface of each of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g in a matrix pattern. A film deposited on the front surface may be, for example, a protection film protecting a thin film transistor (TFT) at a lower part of a pixel electrode in a case of an organic light-emitting display, or an organic-inorganic composite film at an upper part of an organic light-emitting device to protect the organic light-emitting device. When a film or layer is formed and patterned on a front surface during a manufacturing process, the deposition chamber may be used to form the film or layer on the front surface even when the film or layer is not on the front surface of the final display. In one embodiment, the organic light-emitting device used herein includes a pixel electrode, a counter electrode facing the pixel electrode, and an interlayer interposed therebetween and having an emission layer. The organic light-emitting device may be formed on each (sub)pixel. Here, the interlayer may include a layer of an organic material.

The mother substrate 10 may go through various treatments before being inserted into the deposition chamber. For example, before being inserted into the deposition chamber, a TFT may be formed in each pixel region in each of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g, or an emission layer may be formed at each of pixel regions in an organic-light emitting display.

Referring now to FIG. 2, a deposition source 200 may be in the deposition chamber, and the deposition source 200 may move in one direction (e.g., a +x direction) or the opposite direction (e.g., a −x direction). The deposition source 200 may release a deposition material while moving (e.g., repeatedly moving) in the one direction (e.g., a +x direction) and the opposite direction (e.g., a −x direction).

The deposition material released from the deposition source 200 may be deposited on the mother substrate 10 after passing through the mask 100. Here, the mask 100 has the plurality of stripe-shaped masking sheets 121, 122 that are arranged in the one direction (e.g., +x direction) along which the deposition source 200 moves. Thus, in the vicinity of areas of the mother substrate 10 corresponding to the masking sheets 121, a film to be deposited is not affected by the masking sheets 121, 122, and thus, a layer of a uniform thickness may be formed on each of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g having a matrix pattern.

That is, as shown in FIG. 2, when the deposition material is released as the deposition source 200 moves (e.g., repeatedly moves) in the one direction (e.g. a +x direction) and the opposite direction (e.g., a −x direction) while the mask 100 is arranged so as the plurality of parallel stripe-shaped masking sheets 121, 122 of the mask 100, which extend in the one direction (e.g., a +x direction), a thickness of an edge part of a first region deposition layer 11 in a direction of a second region deposition layer 12 may be approximately uniform with a thickness of another part of the first region deposition layer 11 in formation of the first region deposition layer 11 on the mother substrate 10 as shown in FIG. 3. Also, a thickness of an edge part of a third region deposition layer 13 in a direction of the second region deposition layer 12 may be approximately uniform with a thickness of another part of the third region deposition layer 13. This is because only the masking sheets 121, 122 extended in a direction (+x direction or −x direction) along which the deposition source 200 moves are present, but masking sheets extended in a direction crossing a direction (+x direction or −x direction) along which the deposition source 200 moves are not present.

FIG. 4 is a perspective view schematically showing a mask that may be used in a method of manufacturing a display according to a comparative example. When a mask 100′ illustrated in FIG. 4 is used to deposit a material on a mother substrate, a deposition film having a uniform thickness may not be formed. Particularly, as shown in FIG. 4, if the mask 100′ has masking sheets 131′, 132′, 133′, 134′, 135′, and 136′ extending in a first direction (e.g., a +y direction) crossing a second direction (e.g., +a x direction or a −x direction) as well as masking sheets 121′, 122′ extending in the second direction (e.g., a +x direction or −x direction) along which a deposition source moves, a uniform film may not be deposited by using the mask 100′.

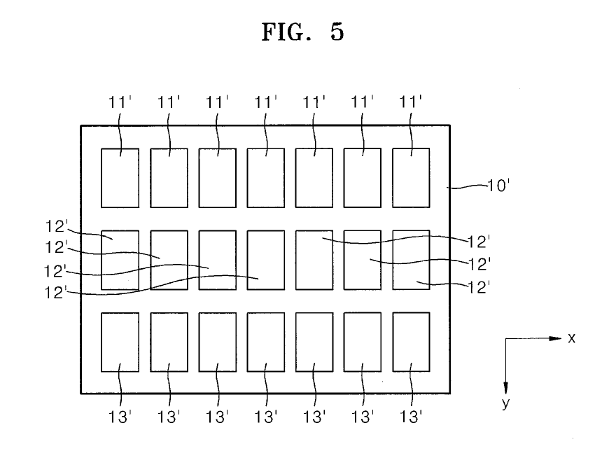

When a material is deposited on the mother substrate 10′ by using the mask 100′, deposition layers each corresponding to a plurality of regions having a matrix pattern of the mother substrate 10′ may be formed as shown in FIG. 5. FIG. 5 is a plan view schematically illustrating a display manufactured by a process according to a comparative example. In this regard, for example, a plurality of first region deposition layers 11′, a plurality of second region deposition layers 12′, and a plurality of third region deposition layers 13′ are formed. In this case, a thickness uniformity may be decreased as a thickness of parts of the plurality of first region deposition layers 11′ adjacent to one another is formed thicker than a thickness of a center part of each of the plurality of first region deposition layers 11′. This is because a shadow effect occurs around the masking sheets 131′, 132′, 133′, 134′, 135′, and 136′ by the masking sheets 131′, 132′, 133′, 134′, 135′, and 136′ extending in the direction (e.g., a +y direction) crossing the direction (e.g., a +x direction or −x direction) along which the deposition source moves.

In order to reduce effects of the shadow effect, widths of the masking sheets 131′, 132′, 133′, 134′, 135′, and 136′ extending in one direction (e.g., a +y direction) crossing another direction (e.g., a +x direction or −direction) along which the deposition source moves may be considered. However, a lifespan of the masking sheets 131′, 132′, 133′, 134′, 135′, and 136′ having thin widths is short, and thus, a lifespan of the mask 100′ itself may be reduced.

However, in the case of the method of manufacturing a display according to the current embodiment of the present invention, a mask does not have masking sheets extended in one direction (e.g., a +y direction) crossing another direction (e.g., +x direction or -x direction) along which a deposition source moves. Thus, a condition that causes the shadow effect may be eliminated.

When an encapsulating film is formed after forming a display unit having a pixel as an organic light-emitting device on each of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g having a matrix pattern of the mother substrate 10, it is desirable for a thickness of the encapsulation film to be uniform. The organic light-emitting device is easily deteriorated by moisture or oxygen, and thus, the encapsulation film serves to block penetration of impurities, such as moisture or oxygen, into the organic light-emitting device inside the encapsulation film.

However, when organic light-emitting displays are manufactured by using the mask 100′ illustrated in FIG. 3 according to the comparison method of manufacturing a display as illustrated in FIG. 4, the encapsulation film formed in the manner described above has a thinner thickness at an edge part in a direction (e.g., a +x direction or −x direction) along which the deposition source moves than a thickness at a center part in each of the organic light-emitting displays. Therefore, the encapsulation film may not effectively prevent penetration of impurities, such as moisture or oxygen. On the other hand, according to the method of manufacturing a display of the current embodiment, the mask does not have masking sheets extended in one direction (e.g., a +y direction) crossing another direction (e.g., a +x direction or −x direction) along which a deposition source moves, and thus, the encapsulation film may have a uniform thickness.

According to one embodiment, the mask 100 may only include the masking sheets 121, 122 extending in one direction (e.g., a +x direction), and thus, a manufacturing process of the mask 100 may be simplified, and a raw material cost used in manufacturing the mask 100 may be reduced.

The masking sheets 121, 122 of the mask 100 may correspond to gaps between rows of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g having a matrix pattern of the mother substrate 10, wherein the rows are arranged in one direction (e.g., a +x direction). Accordingly, gaps between the first region deposition layer 11 covering the plurality of regions 11a, 11b, 11c, 11d, 11e, 11f, and 11g, the second region deposition layer 12 covering the plurality of regions 12a, 12b, 12c, 12d, 12e, 12f, and 12g, and the third region deposition layer 13 covering the plurality of regions 13a, 13b, 13c, 13d, 13e, 13f, and 13g shown in FIG. 3 may be masked by the masking sheets 121, 122, and thus, a material may not be deposited at the gaps.

After forming a display unit including an organic light-emitting device at a pixel in each of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g having a matrix pattern of the mother substrate 10 and including an encapsulation film, the mother substrate 10 may be cut along a periphery of each of the display units to obtain a plurality of displays.

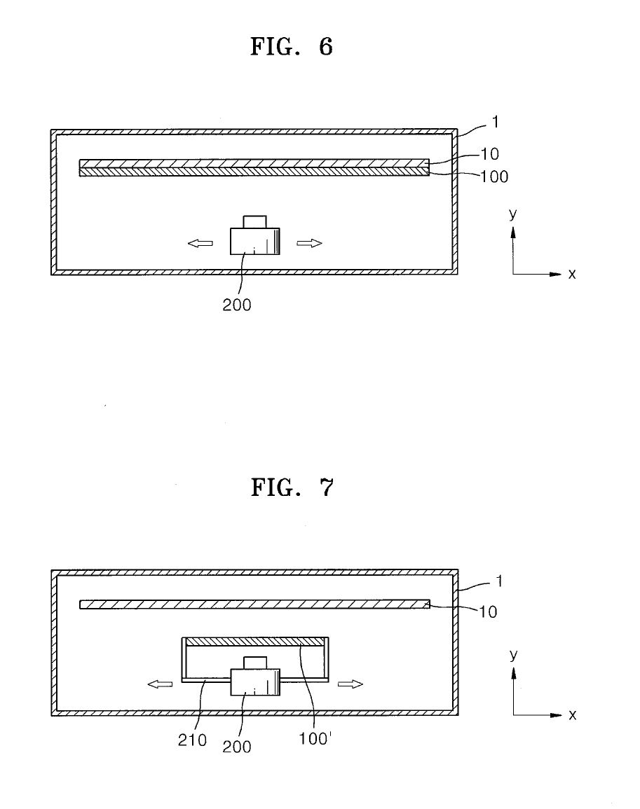

Although the mask 100 and the mother substrate 10 are shown spaced apart from each other in FIG. 2, an embodiment of the present invention is not limited thereto. For example, during a depositing process, the mask 100 and the mother substrate 10 may be separated by a predetermined distance or the mask 100 and the mother substrate 10 may be arranged to be adhering to (or touching or attached to) each other as shown in FIG. 6.

FIG. 6 is a side cross-sectional conceptual view schematically illustrating a manufacturing process according to an embodiment of the present invention. As shown in FIG. 6, the deposition source 200 inside a deposition chamber 1 may release a material when moving back and forth, for example moving in one direction (e.g., a +x direction) to which a plurality of masking sheets of the mask 100 extend and then moving in the opposite direction (e.g., a −x direction), while a location of the mask 100 on the mother substrate 10 is fixed, but an embodiment of the present invention is not limited thereto. For example, a location of the deposition source 200 may be fixed, and a material released from the deposition source 200 may be deposited on the mother substrate 10 by moving the mother substrate 10 and the mask 100 adhered to each other back and forth.

According to one embodiment, a material may be deposited on the mother substrate 10 by moving the mother substrate 10 while a location of the deposition source 200 of the mask 100 may be fixed. FIG. 7 is a side cross-sectional conceptual view schematically illustrating a manufacturing process according to another embodiment of the present invention. As shown in FIG. 7, relative locations of the mask 100 and the deposition source 200 may be fixed by a supporting unit 210, a material may be deposited on the mother substrate 10 by moving the mother substrate 10 back and forth, for example moving in one direction (e.g., a +x direction) to which the plurality of masking sheets of the mask 100 extend and then moving in the opposite direction (e.g., a −x direction).

According to one embodiment, a material may be deposited on the mother substrate 10 by moving a corporate body of the mask 100 and the deposition source 200 back and forth, for example, moving in one direction (e.g., a +x direction) to which the plurality of masking sheets of the mask 100 extend and moving in the opposite direction (e.g., a −x direction), while a location of the mother substrate 10 in the deposition chamber 1 is fixed. Here, relative locations of the mask 100 and the deposition source 200 are fixed by the supporting unit 210 as shown in FIG. 7.

While illustrative embodiments of methods for manufacturing a display have been described, embodiments of the present invention are not limited thereto. For example, a deposition apparatus may be also included in a scope of the present invention.

The deposition apparatus according to an embodiment of the present invention may have structure shown in FIG. 2.

The deposition apparatus according to an embodiment of the present invention may include a deposition chamber including the deposition source 200, which may be movable in one direction (e.g., a +x direction) and the opposite direction (e.g., a −x direction); and may include the mask 100 including a plurality of stripe-shaped masking sheets 121, 122 parallel to one another, wherein the masking sheets 121, 122 may be arranged to extend in a direction (e.g., a +x direction) that the deposition source moves. In the present deposition apparatus, when a material is deposited on an inserted mother substrate 10, a location of the mask 100 with respect to the mother substrate 10 may be fixed, and the deposition source 200 may move back and forth, for example, may move in one direction (e.g., a +x direction) and the opposite direction (e.g., a −x direction) as shown in FIG. 6.

According to one embodiment, when a material is deposited on an inserted mother substrate 10, a location of the mask 100 with respect to the deposition source 200 may be fixed, for example, by the supporting unit 210 as shown in FIG. 7. In this case, the deposition may be performed by moving the corporate body of the mask 100 and the deposition source 200 back and forth, for example, moving in one direction (e.g., a +x direction) to which the plurality of masking sheets of the mask 100 extend and the opposite direction (e.g., a −x direction), with respect to the mother substrate 10. Also, the deposition may be performed by moving the mother substrate 10 back and forth with respect to the corporate body of the mask 100 and the deposition source 200.

In the deposition apparatus according to an embodiment of the present invention, the mask 100 does not have masking sheets that extend in another direction crossing the one direction (e.g., a +x direction) to which the masking sheets 121, 122 extend, and thus, a high thickness uniformity of a film deposited on the mother substrate 10 may be maintained.

The mother substrate 10 to which a film is deposited by using the deposition apparatus according to an embodiment of the present invention, may include a plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g of a matrix pattern on which a plurality of display units may be formed. Also, the masking sheets 121, 122 of the mask 100 may correspond to gaps between rows of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g of the mother substrate 10 arranged in one direction (e.g., a +x direction).

The deposition apparatus according to an embodiment of the present invention may deposit a material on a front surface of each of the corresponding regions of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g of a matrix pattern of the mother substrate 10. A film deposited on the front surface may be, for example, a protection film protecting a TFT at a lower part of a pixel electrode of an organic light-emitting display, or an organic-inorganic composite film at an upper part of an organic light-emitting device for protecting the organic light-emitting device. When a film or layer is formed and patterned on a front surface during a manufacturing process, the deposition apparatus may be used to form the film or layer on the front surface even when the film or layer is not on the front surface of the final display.

Although forming a display unit having an organic light-emitting device in a pixel of the display unit on each of the plurality of regions 11a, 11b, 11c, 11d, 11e, 11f, 11g, 12a, 12b, 12c, 12d, 12e, 12f, 12g, 13a, 13b, 13c, 13d, 13e, 13f, and 13g having a matrix pattern of the mother substrate 10 has been described, an embodiment of the present invention is not limited thereto. For example, the display unit may include a field emission device or a liquid crystal display device.

As described above, according to the embodiments of the present invention, a method of manufacturing a display that may reduce deposition nonuniformity while manufacturing a plurality of displays at the same time, and a deposition apparatus that may be used in the method may be provided. However, the scope of the present invention is not limited to the above effects.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. A method of manufacturing a plurality of displays, the method comprising:
preparing a mother substrate having a plurality of regions in a matrix pattern, the mother substrate being for forming a plurality of display units corresponding to the plurality of regions;
inserting the mother substrate into a deposition chamber, wherein a deposition source movable in a first direction or a second direction opposite to the first direction is in the deposition chamber;
depositing a material on the mother substrate by using a mask comprising a plurality of parallel stripe-shaped masking sheets extending in the first direction; and
cutting the mother substrate along a periphery of each of the plurality of display units to obtain the plurality of displays.

2. The method of claim 1, wherein the depositing of the material on the mother substrate comprises depositing the material on the mother substrate while a location of the mask with respect to the mother substrate is fixed.

3. The method of claim 1, wherein the masking sheets of the mask correspond to gaps between rows of the plurality of regions of the mother substrate arranged in the first direction.

4. The method of claim 1, wherein the mask does not have masking sheets extending in a third direction crossing the first direction.

5. The method of claim 1, wherein each of the plurality of display units comprises an organic light-emitting device.

6. A method of manufacturing a plurality of displays, the method comprising:
preparing a mother substrate having a plurality of regions in a matrix pattern, the mother substrate being for forming a plurality of display units corresponding to the plurality of regions;
inserting the mother substrate into a deposition chamber comprising a deposition source;
depositing a material on the mother substrate by using a mask comprising a plurality of parallel stripe-shaped masking sheets extending in a first direction while moving the mother substrate in at least one of the first direction and a second direction opposite to the first direction; and
cutting the mother substrate along a periphery of each of the plurality of display units to obtain the plurality of displays.

7. The method of claim 6, wherein the depositing of the material on the mother substrate comprises depositing the material on the mother substrate while moving the mother substrate and while a location of the mask with respect to the deposition source is fixed.

8. The method of claim 6, wherein the depositing of the material on the mother substrate comprises depositing the material on the mother substrate while a location of the mask with respect to the mother substrate is fixed.

9. The method of claim 6, wherein the masking sheets of the mask correspond to gaps between rows of the plurality of regions of the mother substrate arranged in the first direction.

10. The method of claim 6, wherein the mask does not have masking sheets extending in a third direction crossing the first direction.

11. The method of claim 6, wherein each of the plurality of display units comprises an organic light-emitting device.

12. A deposition apparatus comprising:
a deposition chamber comprising a deposition source movable in a first direction and a second direction opposite to the first direction; and
a mask comprising a plurality of parallel stripe-shaped masking sheets extending in the first direction.

13. The deposition apparatus of claim 12, wherein a location of the mask with respect to an inserted mother substrate is fixed when a material is deposited on the inserted mother substrate.

14. The deposition apparatus of claim 12,
wherein a mother substrate has a plurality of regions in a matrix pattern, the mother substrate being for forming a plurality of display units corresponding to the plurality of regions,
and wherein the masking sheets of the mask correspond to gaps between rows of the plurality of regions of the mother substrate arranged in the first direction.

15. The deposition apparatus of claim 12, wherein the mask does not have masking sheets extending in a third direction crossing the first direction.

16. A deposition apparatus comprising:
a deposition chamber comprising a deposition source;
a mask comprising a plurality of parallel stripe-shaped masking sheets extending in a first direction; and
a transfer unit in the deposition chamber, wherein the transfer unit delivers an inserted mother substrate in at least one of the first direction and a second direction opposite to the first direction while depositing a material on the inserted mother substrate.

17. The deposition apparatus of claim 16, wherein a location of the mask with respect to the deposition source is fixed when the material is deposited on the inserted mother substrate.

18. The deposition apparatus of claim 16, wherein a location of the mask with respect to the inserted mother substrate is fixed when the material is deposited on the inserted mother substrate.

19. The deposition apparatus of claim 16, wherein the inserted mother substrate has a plurality of regions in a matrix pattern,
wherein the mother substrate is for forming a plurality of display units corresponding to the plurality of regions, and
wherein the masking sheets of the mask correspond to gaps between rows of the plurality of regions of the mother substrate arranged in the first direction.

20. The deposition apparatus of claim 16, wherein the mask does not have masking sheets extending in a third direction crossing the first direction.
